(19) United States
(12) Patent Application Publication
(10) Pub. No.: US 2009/0262499 A1
(43) Pub. Date: Oct. 22, 2009

(54) ELECTRONIC SYSTEM WITH GUIDE APPARATUS FOR GUIDING AIR FLOW THEREIN

(75) Inventor: MING-DER CHOU, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/182,112

(22) Filed: Jul. 29, 2008

(30) Foreign Application Priority Data
Apr. 22, 2008 (CN) 200810301255.6

(51) Int. Cl. H05K 7/20

(52) U.S. Cl. 361/695

(57) ABSTRACT

An electronic system includes a case, a plurality of fans, a plurality of shafts, at least one leaf member, and a plurality of elastic elements. The case defines a plurality of exits. The fans are fixed in the case corresponding to the exits. The shafts are fixed in the case corresponding to the fans. The at least one leaf member is rotationally mounted to one of the shafts. The elastic elements are mounted to one of the shafts to bias the at least one leaf member to close the corresponding exit. A guide apparatus for the electronic system is provided as well.

### BACKGROUND

1. Field of the Invention

The present invention generally relates to electronic systems and apparatuses for heat dissipation, and particularly, to an electronic system and a guide apparatus for guiding air flow in the electronic system.

2. Description of Related Art

A conventional electronic system generates a lot of heat during operation. The heat should be dissipated in time, otherwise damage to the system may occur. Electronic systems normally use fans and heatsinks therein for dissipating heat. Referring to FIG. 6, two fans 102 and 104 are incorporated in the electronic system 10 for heat dissipation. Improvements in electronic technology have resulted in faster-running electronic elements, which unfortunately generate more heat. As a result, additional heat dissipation means should be added in those electronic systems.

However, referring to FIG. 7, in case that one of the fans 102 or 104 malfunctions, refluence of hot air driven out by the working fan back into the system 10 through the broken fan can occur, thus lowers heat dissipation efficiency.

### BRIEF DESCRIPTION OF THE DRAWINGS

FIG. 1 is a schematic diagram of an electronic system in accordance with a first exemplary embodiment;

FIG. 2 is a schematic diagram of the electronic system of FIG. 1, showing a working state;

FIG. 3 is an isometric view of an electronic system in accordance with a second exemplary embodiment;

FIG. 4 is similar to FIG. 3, but showing the electronic system in a working state;

FIG. 5 is an isometric view of an electronic system in accordance with a third exemplary embodiment;

FIG. 6 is a schematic diagram of an electronic system in prior art, illustrating air flow in the electronic system; and

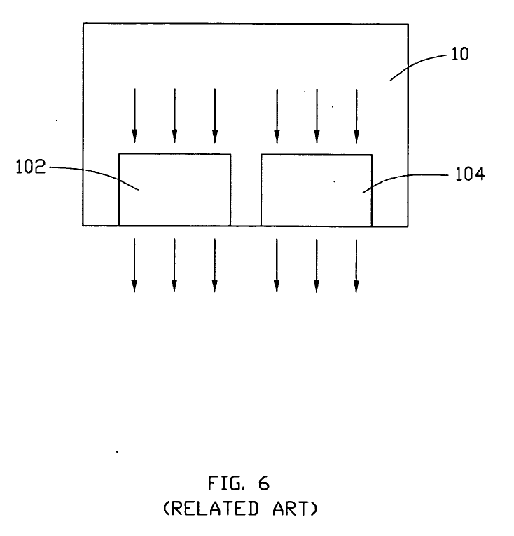

FIG. 7 is similar to FIG. 6, but illustrating refluence of hot air.

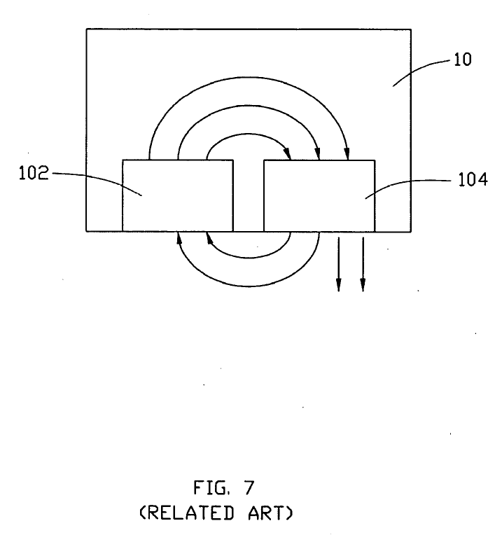

### DETAILED DESCRIPTION

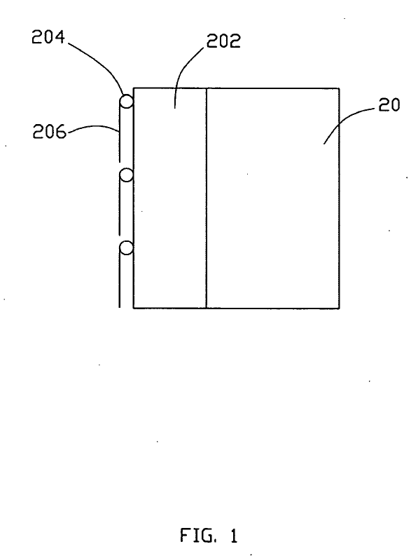

Referring to FIG. 1, an electronic system in accordance with a first exemplary embodiment includes a case 20, a fan 202 mounted in the case 20 for blowing out hot air, a number of shafts 204 fixed to an exit at a side of the case 20 adjacent to the fan 202, and a leaf 206 attached to and rotatable with each corresponding shaft 204.

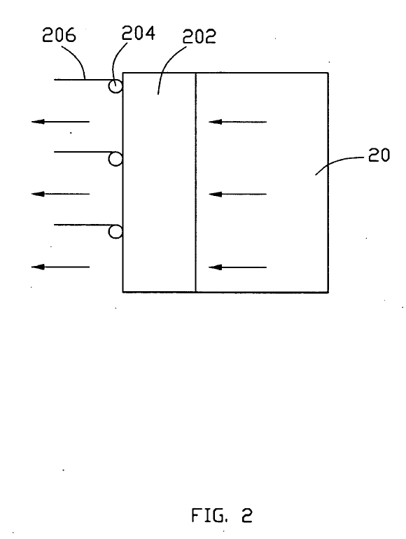

Referring to FIG. 2, when the fan 202 is in operation, hot air is blown out from the case 20. The hot air drives the leaves 206 to rotate about the shafts 204 respectively, therefore opening the exit to allow the hot air to be discharged from the case 20.

When the fan 202 is not in operation, no air is blown out to drive the leaves 206 to rotate about the shafts 204. Therefore, driven by the gravity force, the leaves 206 are hung on the shafts 204 and close the exits. By this, external air cannot enter the electronic system through the exit of the case 20, thus refluence of hot air is avoided.

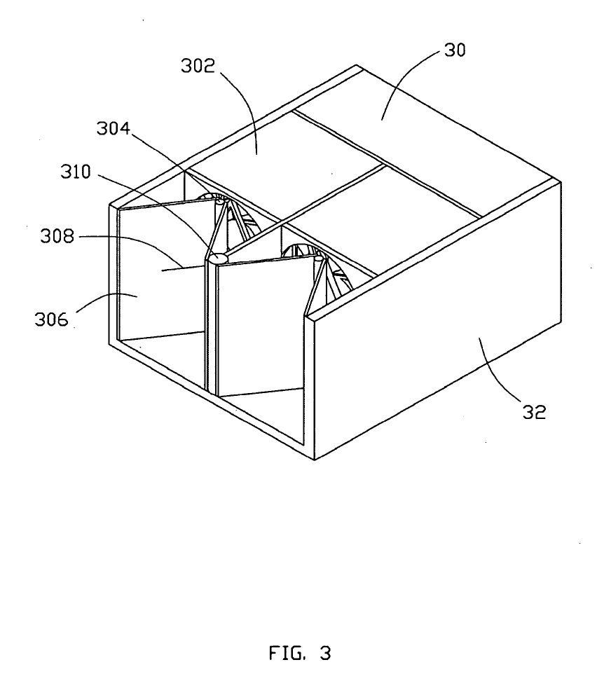

Referring to FIG. 3, an electronic system in accordance with a second exemplary embodiment includes a case 30 defining two parallel sidewalls 32, a plurality of exits, a plurality of fans 302 fixed inside the case 30 aligning with the corresponding exits, and a plurality of guide apparatuses located at the corresponding exits of the case 30 for guiding air flow. Each guide apparatus includes a shaft 304 mounted to the case 30, two leaves 306, a torsion spring 308, and a stand pole 310. The leaves 306 are rotational mounted to the shaft 304. The torsion spring 308 is mounted to the shafts 304 and resists against the leaves 306 with two free ends thereof, to bias distal ends of the leaves 306 to resist against the corresponding stand poles 310 at opposite sides of the shaft 304, or resist against the corresponding stand pole 310 and one of the sidewall 32 respectively. Therefore, the leaves 306 are capable of shielding the corresponding exit of the case 30, thus preventing external air to flow into the case 30. Over-rotation of the leaves 306 is prevented by the stand pole 310 and the sidewall 32, blocking distal ends of the leaves 306.

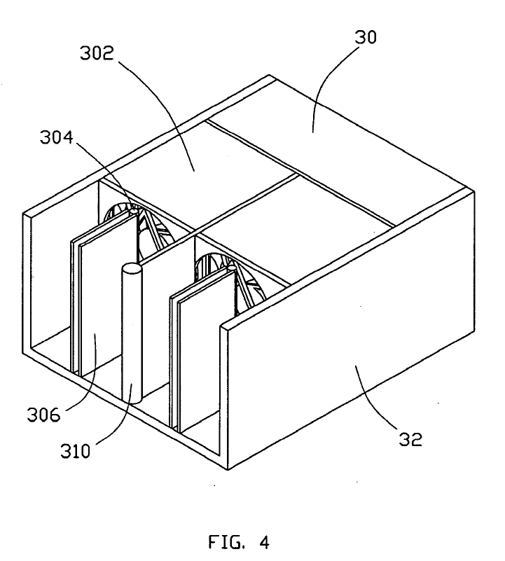

Referring to FIG. 4, when the fans 302 are in operation, hot air are blown out from the case 30. The hot air drives the leaves 306 to rotate about the corresponding shafts 304, overcoming the torsion force of the torsion springs 308. The exits of the case 30 are open to allow the hot air to be blown out of the case 30. Once any fan 302 stops working, the corresponding torsion spring 308 bias the corresponding leaves 306 to rotate back to cover the exit, therefore preventing hot air blown out by other fans 302 to enter the case 30. Thus, refluence of hot air is avoided.

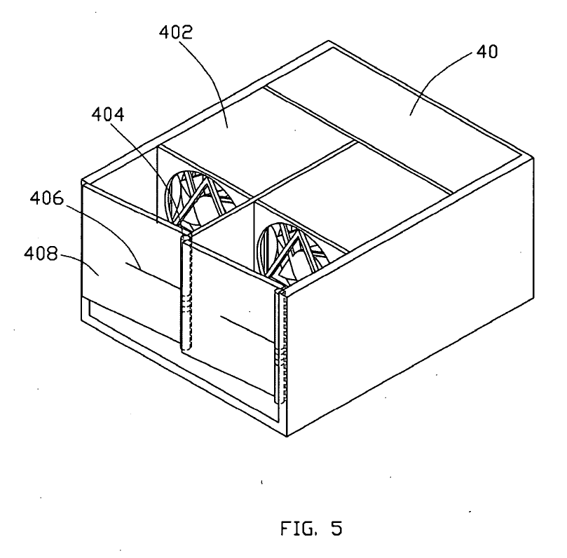

Referring to FIG. 5, an electronic system in accordance with a third embodiment includes a case 40 defining a plurality of exits, a plurality of fans 402 fixed inside the case 40 at one side thereof and aligning with the corresponding exits, and a plurality of guide apparatuses located at the corresponding exits. The exits allow hot air in the case 40 to be blown out by the fans 402. Each guide apparatus includes a shaft 404, a leaf 408 rotationally mounted to the shaft 404, and a torsion spring 406 mounted to the shaft 404 to bias the leaf 408 to cover the exit. When the fans 402 are in operation, the air flows blown out by the fans 402 overcomes the forces of the torsion springs 406 to rotate the leaves 408 and open the exits; when the fans 402 are idle, the torsion springs 406 will keep the leaves 408 in positions to close the exits.

The embodiments were chosen and described in order to explain the principles of the invention and their practical application so as to enable others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

What is claimed is:

1. An electronic system comprising:
a case defining a plurality of exits;
a plurality of fans fixed in the case corresponding to the exits;
a plurality of shafts fixed in the case corresponding to the fans;
at least one leaf member rotationally mounted to one of the shafts; and
a plurality of elastic elements each mounted to one of the shafts to bias the at least one leaf member to close the corresponding exit.

2. The electronic system as described in claim 1, wherein the at least one leaf member comprises two leaf members rotationally mounted to one of the shafts, the leaf members are capable of rotating reversely to close the corresponding exit via elasticity of a corresponding elastic element.

3. The electronic system as described in claim 2, further comprising two stand poles fixed in the case at opposite sides of one of the shafts, wherein distal ends of the leaf members are biased by the elastic element to resist against the stand poles, respectively.

4. The electronic system as described in claim 2, further comprising a stand pole fixed in the case at a side of one of the shafts, wherein the case comprises a sidewall at an opposite side of the one of the shafts, distal ends of the leaf members are biased by the elastic element to resist against the stand pole and the sidewall, respectively.

5. The electronic system as described in claim 1, wherein the at least one leaf member is able to be driven by the air blown out by the corresponding fan to rotate about the shaft to open the corresponding exit, against the corresponding elastic element.

6. The electronic system as described in claim 1, wherein the elastic elements are torsion springs.

7. A guide apparatus comprising:
a shaft;
at least one leaf rotationally mounted the shaft; and
an elastic element fixed to the shaft to bias the at least one leaf; the at least one leaf is capable of being blown by air flow to rotate against the elastic element.

8. The guide apparatus as described in claim 7, wherein the at least one leaf comprises two leaves rotationally mounted to the shaft, the elastic element biases the leaves to spread towards reverse directions.

9. The guide apparatus as described in claim 7, further comprising a stand pole located at a side of the shaft, wherein a distal end opposite to the shaft of the at least one leaf resists against the stand pole when the at least one leaf is spread.

10. The guidance apparatus as described in claim 7, wherein the elastic element is a torsion spring.
